(19) United States
(12) Patent Application Publication
(10) Pub. No.: US 2025/0204202 A1
(43) Pub. Date: Jun. 19, 2025

(54) ORGANIC LIGHT EMITTING DIODE DISPLAY DEVICE AND HEAD MOUNTED DISPLAY COMPRISING SAME

(71) Applicant: LG Display Co., Ltd., Seoul (KR)

(72) Inventors: Seungmin Baik, Gimpo-si (KR); Sein Son, Seoul (KR); Kisuk Kang, Seoul (KR)

(73) Assignee: LG Display Co., Ltd., Seoul (KR)

(21) Appl. No.: 18/795,771

(22) Filed: Aug. 6, 2024

(30) Foreign Application Priority Data
Dec. 15, 2023 (KR) 10-2023-0183399

(51) Int. Cl. H10K 59/80; H10K 59/122; H10K 59/131

(52) U.S. Cl. CPC H10K 59/80516; H10K 59/122; H10K 59/131

(57) ABSTRACT

An organic light emitting diode display device includes a first insulating layer on a substrate; a first reflective electrode on the first insulating layer in a first sub-pixel; a second insulating layer on the first reflective electrode and the first insulating layer; a second reflective electrode on the second insulating layer in a second sub-pixel; a third insulating layer on the second reflective electrode and the second insulating layer; a third reflective electrode on the third insulating layer in a third sub-pixel; trenches in the third insulating layer at boundary areas between the sub-pixels; first step compensation electrodes on the first insulating layer at opposite sides of the second sub-pixel, each first step compensation electrode partially overlapping a trench; and second step compensation electrodes on the second insulating layer at opposite sides of the first sub-pixel and the third sub-pixel, each second step compensation electrode partially overlapping a trench.

The present application claims priority to Korean Patent Application No. 10-2023-0183399, filed Dec. 15, 2023, the entire contents of which is incorporated herein for all purposes by this reference.

### BACKGROUND

### Technical Field

The present disclosure relates to an organic light emitting diode display device, and a head mounted display device including the same.

### Discussion of the Related Art

Organic light emitting diode display devices, as a self-luminous type display device, have a wider viewing angle and a higher contrast ratio than liquid crystal display devices and are lighter and thinner and have low consumed power because they do not require a separate backlight. In addition, the organic light emitting diode display devices have the advantages of low DC voltage driving, fast response time, and especially, inexpensive manufacturing cost.

Recently, head mounted display devices including the organic light emitting diode display device have been developed. A head mounted display (HMD) device is an image display device that is worn on a user's head in the form of glasses or a helmet and focuses on a distance near the user's eyes. The head mounted display device can implement virtual reality (VR) or augmented reality (AR). A high-resolution and small-sized organic light emitting diode display device is applied to the head mounted display device.

### SUMMARY

In an organic light emitting diode display device, light emitting layers that emit light of different colors, such as red, green, and blue, for each sub-pixel may be formed individually, or a light emitting layer that emits light of a single color, such as white light, may be commonly formed on all sub-pixels.

However, when the light emitting layer that emits light of a single color, such as white light, is formed on all sub-pixels, a separate mask for forming the light emitting layer that emits light of different colors for each sub-pixel is not required, and thus a problem due to misalignment of a mask process, etc. does not occur.

When the light emitting layer is formed to emit light of a single color, such as white light, in all sub-pixels, a color filter should be additionally provided to implement different colors for each sub-pixel, and thus, there is a disadvantage in that light emitted from light emitted from the light emitting layer is absorbed by the color filter, thereby reducing light extraction efficiency.

In addition, when the light emitting layer is formed to emit light of a single color, such as white light, in all sub-pixels, charges move through the light emitting layer between neighboring sub-pixels, resulting in a leakage current between the sub-pixels, and as a result, there is a problem that the image quality of the organic light emitting display device is degraded.

Accordingly, embodiments of the present disclosure are directed to an organic light emitting diode display device and a head mounted display comprising same that substantially obviates one or more of the problems due to limitations and disadvantages of the related art.

An aspect of the present disclosure is to provide an organic light emitting diode display device including an electrode structure that can prevent a leakage current between sub-pixels and increase light extraction efficiency.

Another aspect of the present disclosure is to provide a display device in which a leakage current between sub-pixels can be prevented and light extraction efficiency can be increased.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, an organic light emitting diode display device comprising an active area having a first sub-pixel, a second sub-pixel, and a third sub-pixel, and a non-active area adjacent to the active area, the organic light emitting diode display device comprises a substrate; a first insulating layer on the substrate; a first reflective electrode on the first insulating layer in the first sub-pixel; a first step compensation electrodes on the first insulating layer at a first boundary area between the first and second sub-pixels and at a first boundary area between the second and third subpixels; a second insulating layer on the first insulating layer, and covering the first reflective electrode and the first step compensation electrodes; a second reflective electrode on the second insulating layer in the second sub-pixel; second step compensation electrodes on the first insulating layer at the first boundary area and at the second boundary area; a third insulating layer on the second insulating layer, and covering the second reflective electrode and the second step compensation electrodes; and a third reflective electrode on the third insulating layer in the third sub-pixel, wherein trenches are defined in the third insulating layer respectively at the first and second boundary areas; wherein each one of the first step compensation electrodes partially overlap a respective one the trenches in a plan view, and wherein each one of the second step compensation electrodes partially overlap a respective one of the trenches in a plan view.

In another aspect, a head mounted display device, comprises a left-eye eyepiece and a right-eye eyepiece; and a left-eye display device and a right-eye display device configured to provide an image to the left-eye eyepiece and the right-eye eyepiece, wherein each of the left-eye display device and the right-eye display device respectively includes the organic light emitting diode display device as described herein.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain various principles.

FIG. 1 is a schematic plan view showing a pixel of an organic light emitting diode display device according to one embodiment of the present disclosure.

FIG. 2 is a schematic cross-sectional view showing the pixel of the organic light emitting diode display device according to one embodiment of the present disclosure, which is a cross-sectional view along line 2-2 in FIG. 1.

FIG. 3 is a schematic cross-sectional view showing the pixel of the organic light emitting diode display device according to one embodiment of the present disclosure, which is a cross-sectional view along line 3-3 in FIG. 1.

FIG. 4 is an enlarged view of area 4 in FIG. 2.

FIG. 5 is a schematic cross-sectional view of a light emitting layer according to one embodiment of the present disclosure.

FIGS. 6 to 15 are schematic views for describing a method of manufacturing an organic light emitting diode display device according to one embodiment of the present disclosure, in which FIGS. 6, 8, 10, 12, and 14 are plan views, and FIGS. 7, 9, 11, 13, and 15 are cross-sectional views.

FIG. 16 is a schematic plan view showing the pixel of the organic light emitting diode display device according to one embodiment of the present disclosure.

FIG. 17 is a schematic cross-sectional view showing the organic light emitting diode display device according to one embodiment of the present disclosure, which is a cross-sectional view along line 17-17 in FIG. 16.

FIG. 18 is a schematic cross-sectional view showing the organic light emitting diode display device according to one embodiment of the present disclosure, which is a cross-sectional view along line 18-18 in FIG. 16.

FIG. 19 is a schematic plan view showing the organic light emitting diode display device according to one embodiment of the present disclosure.

FIG. 20 is a schematic cross-sectional view showing the organic light emitting diode display device according to one embodiment of the present disclosure, which is a cross-sectional view along line 20-20 in FIG. 19.

FIG. 21 is a schematic cross-sectional view showing the organic light emitting diode display device according to one embodiment of the present disclosure, which is a cross-sectional view along line 21-21 in FIG. 19.

FIGS. 22 to 24 show a head mounted display device according to one embodiment of the present disclosure.

### DETAILED DESCRIPTION

Advantages and features of the present disclosure and methods for achieving them will become clear with reference to embodiments described below in detail in conjunction with the accompanying drawings. However, the present disclosure is not limited to the embodiments disclosed below but will be implemented in various different forms, these embodiments are merely provided to make the disclosure of the present disclosure complete and fully inform those skilled in the art to which the present disclosure pertains of the scope of the present disclosure.

Since shapes, sizes, ratios, angles, numbers, and the like disclosed in the drawings for describing the embodiments of the present disclosure are illustrative, the present disclosure is not limited to the illustrated items. The same reference number indicates the same components throughout the disclosure. In addition, in describing the present disclosure, when it is determined that the detailed description of a related known technology may unnecessarily obscure the gist of the present disclosure, detailed description thereof will be omitted. When terms “comprises,” “has,” “consists of,” and the like described in the present disclosure are used, other parts may be added unless “only” is used. When a component is expressed in the singular, it includes a case in which the component is provided as a plurality of components unless specifically stated otherwise.

In construing a component, the component is construed as including the margin of error even when there is no separate explicit description.

When the positional relationship is described, for example, when the positional relationship between two parts is described using the term “on,” “above,” “under,” “next to,” or the like, one or more other parts may be positioned between the two parts unless the term “immediately” or “directly” is used.

Although terms, such as first and second, are used to describe various components, the components are not limited by the terms. The terms are only used to distinguish one component from another. Therefore, a first component described below may be a second component within the technical spirit of the present disclosure.

The same reference number indicates the same components throughout the disclosure.

The size and thickness of each component shown in the drawings are shown for convenience of description, and the present disclosure is not necessarily limited to the sizes and thicknesses of the components shown.

Features of various embodiments of the present disclosure can be partially or fully coupled or combined, and as can be fully understood by those skilled in the art, various technical interconnection and operations are possible, and the embodiments may be implemented independently of each other and implemented together in combination thereof.

Hereinafter, an organic light emitting diode display device and a head mounted display device according to embodiments of the present disclosure will be described in detail with reference to the accompanying drawings.

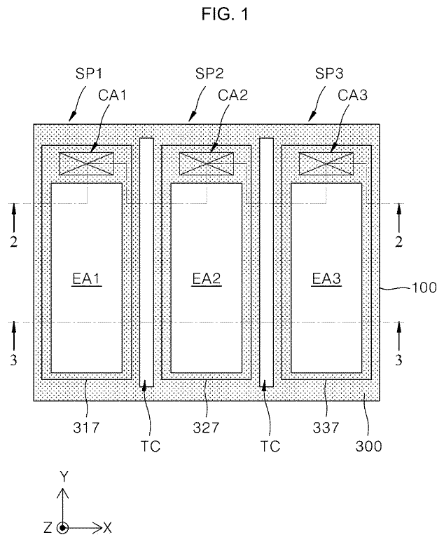

FIG. 1 is a schematic plan view showing a pixel of an organic light emitting diode display device according to one embodiment of the present disclosure. Although a plurality of sub-pixels SP1, SP2, and SP3 are disposed in a matrix form in an active area of the organic light emitting diode display device according to one embodiment of the present disclosure, only one pixel including the three sub-pixels SP1, SP2, and SP3 is shown in FIG. 1.

With reference to FIG. 1, the organic light emitting diode display device according to one embodiment of the present disclosure includes a plurality of anode electrodes 317, 327, and 337, a trench TC, and a bank 300. For example, the plurality of sub-pixels SP1, SP2, and SP3 arranged in an X-axis direction are provided on a substrate 100.

The plurality of emission areas EA1, EA2, and EA3 corresponding to the plurality of sub-pixels SP1, SP2, and SP3 are provided. The first sub-pixel SP1 has the first emission area EA1, the second sub-pixel SP2 has the second emission area EA2, and the third sub-pixel SP3 has the third emission area EA3.

The plurality of emission areas EA1, EA2, and EA3 are defined by the bank 300. Areas exposed without covered by the bank 300 become the plurality of emission areas EA1, EA2, and EA3.

A plurality of anode electrodes 317, 327, and 337 corresponding to the plurality of sub-pixels SP1, SP2, and SP3 are provided. The first anode electrode 317 may be disposed in the first sub-pixel SP1, the second anode electrode 327 may be formed in the second sub-pixel SP2, and the third anode may be disposed in the third sub-pixel SP3. The first to third anode electrodes 317, 327, and 337 may be spaced apart from each other.

A portion of the first anode electrode 317 not covered by the bank 300 can be defined as the first emission area EA1. The first anode electrode 317 of the first sub-pixel SP1 may be connected to at least one transistor disposed on the substrate 100 through a first contact area CA1.

A portion of the second anode electrode 327 not covered by the bank 300 can be defined as the second emission area EA2. The second anode electrode 327 of the second sub-pixel SP2 may be connected to at least one transistor disposed on the substrate 100 through a second contact area CA2.

A portion of the third anode electrode 337 not covered by the bank 300 can be defined as the third emission area EA3. The third anode electrode 337 of the third sub-pixel SP3 may be electrically connected to at least one transistor disposed on the substrate 100 through the third contact area CA3.

The trenches TC extending in a Y-axis direction may be formed in boundary areas between the plurality of sub-pixels SP1, SP2, and SP3. The trench TC may be formed in each of the boundary area between the first sub-pixel SP1 and the second sub-pixel SP2, the boundary area between the second sub-pixel SP2 and the third sub-pixel SP3, and the boundary area between the third sub-pixel SP3 and the first sub-pixel SP1.

A length of the trench TC in the Y-axis direction may be greater than lengths of the plurality of emission areas EA1, EA2, and EA3. The length of the trench TC in the Y-axis direction may be greater than or equal to lengths of the plurality of anode electrodes 317, 327, and 337. The length of the trench TC in the Y-axis direction may extend greater than lengths of the plurality of sub-pixels SP1, SP2, and SP3. The trench TC may extend throughout the active area in the Y direction.

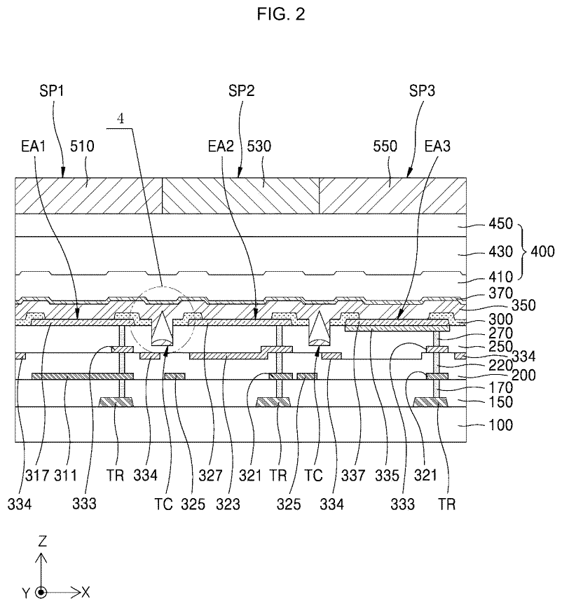

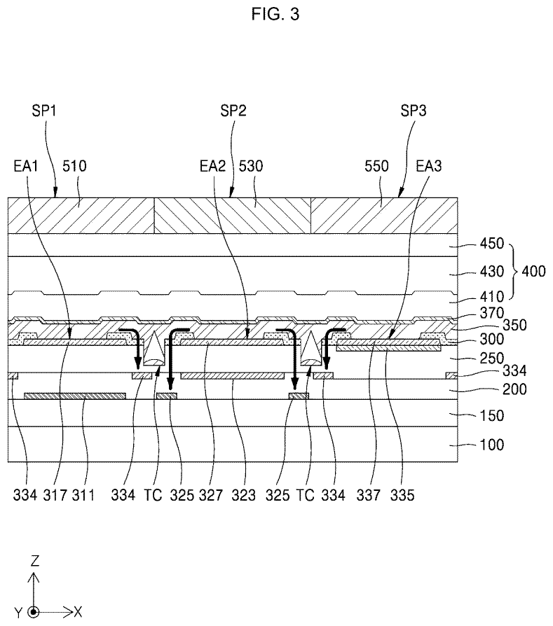

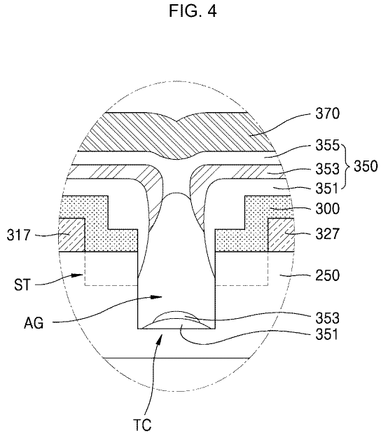

FIGS. 2 and 3 are schematic cross-sectional views showing a pixel of an organic light emitting diode display device according to one embodiment of the present disclosure, in which FIG. 2 is a cross-sectional view along line 2-2 in FIG. 1, and FIG. 3 is a cross-sectional view along line 3-3 in FIG. 1. FIG. 4 is an enlarged view of area 4 in FIG. 2.

With reference to FIGS. 2 and 3, the organic light emitting diode display device according to one embodiment of the present disclosure may include a substrate 100, a driving transistor TR, first to third insulating layers 150, 200, and 250, first to third reflective electrodes 311, 323, and 335, first and second step compensation electrodes 325 and 334, first and second contact electrodes 321 and 333, first to third anode electrodes 317, 327, and 337, a bank 300, a light emitting layer 350, a cathode electrode 370, the trench TC, an encapsulation layer 400, and first to third color filters 510, 530, and 550.

The organic light emitting diode display device according to one embodiment of the present disclosure may be implemented in a so-called top emission type in which light emitted from the light emitting layer 350 is emitted upward.

The substrate 100 may be made of a semiconductor material, such as a silicon wafer. In one embodiment, the substrate 100 may be made of glass or plastic.

For example, the first sub-pixel SP1, the second sub-pixel SP2, and the third sub-pixel SP3 arranged in the X-axis direction are provided on the substrate 100. The first sub-pixel SP1 may emit red light, the second sub-pixel SP2 may emit green light, and the third sub-pixel SP3 may emit blue light. The arrangement order and direction of the sub-pixels SP1, SP2, and SP3 may be changed in any of various ways.

The driving circuit including various signal lines, thin film transistors, capacitors, etc. is provided on the substrate 100 for each of the sub-pixels SP1, SP2, and SP3. Signal lines may include gate lines, data lines, and voltage lines, and transistors may include a switching transistor, a driving transistor TR, and a sensing transistor. For example, the switching transistor, the driving transistor TR, and the sensing transistor may be formed on the substrate 100 using a CMOS process.

The first insulating layer 150 may be disposed on the substrate 100. The first insulating layer 150 may be made of an inorganic insulating material or an organic insulating material. The first insulating layer 150 may cover transistors including driving transistors TR, various signal lines, capacitors, etc. that are disposed on the substrate 100. An additional insulating layer and an additional conductive pattern may be disposed between the substrate 100 and the first insulating layer 150.

The first reflective electrode 311, the first step compensation electrodes 325, and the first contact electrodes 321 may be disposed on the first insulating layer 150. The first reflective electrode 311 may be disposed in the first sub-pixel SP1, and the first contact electrode 321 may be disposed in each of the second sub-pixel SP2 and the third sub-pixel SP3. The first step compensation electrodes 325 may be disposed at both sides of the second sub-pixel SP2. The first step compensation electrodes 325 may be disposed at the left and right sides of the second sub-pixel SP2.

The first reflective electrode 311, the first step compensation electrodes 325, and the first contact electrodes 321 may be provided to be spaced apart from each other and formed in the same thickness. A predetermined first voltage may be applied to the first step compensation electrodes 325. A first voltage lower than voltages of the first to third anode electrodes 317, 327, and 337 to be described below may be applied to the first step compensation electrodes 325.

First contact vias 170 may be disposed to pass through the first insulating layer 150. In the first to third sub-pixels SP1, SP2, and SP3, the first reflective electrode 311 and the first contact electrodes 321 may each be connected to the driving transistor TR through the first contact vias 170 passing through the first insulating layer 150.

After the first contact vias 170 passing through the first insulating layer 150 are first formed, the first reflective electrode 311 and the first contact electrodes 321 may be formed on the first insulating layer 150. In one embodiment, the first reflective electrode 311 and the first contact via 170 may be formed integrally in the first sub-pixel SP1. The first reflective electrode 321 and the first contact via 170 may be formed integrally in the second sub-pixel SP2. The first reflective electrode 321 and the first contact via 170 may be formed integrally in the third sub-pixel SP3.

The first reflective electrode 311, the first step compensation electrodes 325, and the first contact electrodes 321 may be made of a metal material having high reflectivity, such as silver (Ag), a silver alloy, aluminum (Al), or an aluminum alloy. The first reflective electrode 311, the first step compensation electrodes 325, and the first contact electrodes 321 may be made of the same material by the same process. The first contact via 170 may contain a metal material.

The second insulating layer 200 may be disposed on the first insulating layer 150, and the second insulating layer 200 may cover the first reflective electrode 311, the first step compensation electrodes 325, and the first contact electrodes 321. The second insulating layer 200 may be made of an inorganic insulating material or an organic insulating material.

The second reflective electrode 323, the second step compensation electrodes 334, and the second contact electrodes 333 may be disposed on the second insulating layer 200. The second reflective electrode 323 may be disposed in the second sub-pixel SP2, and the second contact electrode 333 may be disposed in each of the first sub-pixel SP1 and the third sub-pixel SP3.

The second step compensation electrodes 334 may be disposed at both sides of the first sub-pixel SP1 and at both sides of the third sub-pixel SP3. The second step compensation electrodes 334 may be disposed at left and right sides of the first sub-pixel SP1 and at left and right sides of the third sub-pixel SP3 in a plan view. The second reflective electrode 323, the second step compensation electrodes 334, and the second contact electrodes 333 may be provided to be spaced apart from each other and formed in the same thickness.

In a top view of the organic light emitting diode display device according to one embodiment of the present disclosure, the second step compensation electrodes 334 may not overlap the first step compensation electrodes 325. In addition, in a top view of the organic light emitting diode display device according to one embodiment of the present disclosure, the second step compensation electrodes 334 may not overlap the first reflective electrode 311.

A predetermined second voltage may be applied to the second step compensation electrodes 334. A second voltage lower than the voltages of the first to third anode electrodes 317, 327, and 337 to be described below may be applied to the second step compensation electrodes 334. The second voltage applied to the second step compensation electrodes 334 may be the same as the first voltage applied to the first step compensation electrodes 325.

In one embodiment, the second voltage applied to the second step compensation electrodes 334 may differ from the first voltage applied to the first step compensation electrodes 325. For example, the first voltage applied to the first step compensation electrodes 325 disposed under the second step compensation electrodes 334 may be lower than the second voltage applied to the second step compensation electrodes 334.

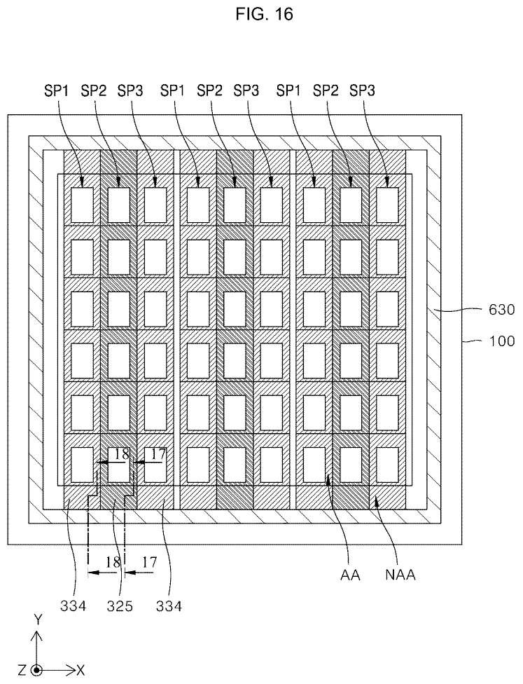

A structure for applying the voltages to the first and second step compensation electrodes 325 and 334 will be described below with reference to FIGS. 16 to 21.

Second contact vias 220 may be disposed to pass through the second insulating layer 200. In the first sub-pixel SP1, the second contact electrode 333 may be electrically connected to the first reflective electrode 311 through the second contact via 220 passing through the second insulating layer 200. In the second sub-pixel SP2, the second reflective electrode 323 may be electrically connected to the first contact electrode 321 through the second contact via 220 passing through the second insulating layer 200. In the third sub-pixel SP3, the second contact electrode 333 may be electrically connected to the first contact electrode 321 through the second contact via 220 passing through the second insulating layer 200.

The second reflective electrode 323 and the second contact electrodes 333 may be made of a metal material having high reflectivity, such as silver (Ag), a silver alloy, aluminum (Al), or an aluminum alloy. The second reflective electrode 323, the second step compensation electrodes 334, and the second contact electrodes 333 may be made of the same material by the same process. The second contact via 220 may contain a metal material. After the second contact vias 220 passing through the second insulating layer 200 are first formed, the second reflective electrode 323 and the second reflective electrode 333 may be formed on the second insulating layer 200.

In one embodiment, the second reflective electrode 333 and the second contact via 220 may be formed integrally in the first sub-pixel SP1. The second reflective electrode 323 and the second contact via 220 may be formed integrally in the second sub-pixel SP2. The second contact electrode 333 and the second contact via 220 may be formed integrally in the third sub-pixel SP3.

The second reflective electrode 323, the second step compensation electrodes 334, and the second contact electrodes 333 may be disposed on the second insulating layer 200. The third insulating layer 250 may be disposed on the second insulating layer 200, and the third insulating layer 250 may cover the second reflective electrode 323, the second step compensation electrodes 334, and the second contact electrodes 333. The third insulating layer 250 may be made of an inorganic insulating material or an organic insulating material.

The first anode electrode 317, the second anode electrode 327, the third reflective electrode 335, the third anode electrode 337 may be disposed on the third insulating layer 250. The first anode electrode 317 may be disposed in the first sub-pixel SP1, the second anode electrode 327 may be disposed in the second sub-pixel SP2, and the third reflective electrode 335 and the third anode electrode 337 may be disposed in the third sub-pixel SP3. In a top view of the organic light emitting diode display device according to one embodiment of the present disclosure, the third reflective electrode 335 and the third anode electrode 337 in the third sub-pixel SP3 may overlap each other, and the third anode electrode 337 may be directly disposed on the third reflective electrode 335. In a top view of the organic light emitting diode display device according to one embodiment of the present disclosure, the first step compensation electrodes 325 do not overlap the second anode electrode 327, and the second step compensation electrodes 334 may not overlap the first and third anode electrodes 317 and 337.

Third contact vias 270 may be disposed to pass through the third insulating layer 250. In the first sub-pixel SP1, the first anode electrode 317 may be electrically connected to the second contact electrode 333 through the third contact via 270 passing through the third insulating layer 250. In the second sub-pixel SP2, the second anode electrode 327 may be electrically connected to the second reflective electrode 323 through the third contact via 270 passing through the third insulating layer 250. In the third sub-pixel SP3, the third reflective electrode 335 may be electrically connected to the second contact electrode 333 through the third contact via 270 passing through the third insulating layer 250.

In one embodiment, instead of the third reflective electrode 335 and the third anode electrode 337 being in contact with each other, an additional insulating layer may be further disposed on the third reflective electrode 335, and the first to third anodes electrodes 317, 327, and 337 may be disposed on the insulating layer. In this case, the third reflective electrode 335 and the third anode electrode 337 may be electrically connected through an additional contact via.

The third reflective electrode 335 may be made of a metal material with high reflectivity, such as silver (Ag), a silver alloy, aluminum (Al), or an aluminum alloy. The third contact via 270 may contain a metal material. The first to third anode electrodes 317, 327, and 337 may be made of a transparent conductive material, such as ITO or IZO, that may transmit light. The first to third anode electrodes 317, 327, and 337 may each be electrically connected to the source terminal or drain terminal of the driving transistor disposed on the substrate 100.

The bank 300 may be disposed to cover edge areas of the first to third anode electrodes 317, 327, and 337 on the third insulating layer 250. Portions of the first to third anode electrodes 317, 327, and 337 exposed without being covered by the bank 300 are defined as emission areas. The bank 300 may be made of an inorganic insulating material. In one embodiment, the bank 300 may be made of an organic insulating material.

The trenches TC having a concave structure are formed in the bank 300 and the third insulating layer 250. The trenches TC may be disposed in the boundary areas between the first to third sub-pixels SP1, SP2, and SP3.

In a top view (or plan view) of the organic light emitting diode display device according to one embodiment of the present disclosure, portions of the first step compensation electrodes 325 disposed under the trenches TC may overlap the trenches TC. The second step compensation electrodes 334 disposed under the trenches TC may partially overlap the trenches TC without overlapping the first step compensation electrodes 325.

The trenches TC may be formed through a process of removing predetermined areas of the bank 300 and the third insulating layer 250. The trenches TC may pass through the bank 300 and extend to a predetermined area of the third insulating layer 250. In one embodiment, lower surfaces of the trenches TC may be in contact with the second step compensation electrodes 334 under the third insulating layer 250.

As described above, by arranging the first step compensation electrodes 325 formed coplanarly with the first reflective electrode 311 of the first sub-pixel SP1 and arranging the second step compensation electrodes 334 formed coplanarly with the second reflective electrode 323 of the second sub-pixel SP2 and not overlapping the first step compensation electrodes 325 under the trenches TC formed in the boundary areas between the first to third sub-pixels SP1, SP2, and SP3, it is possible to prevent the steps from being formed on the third insulating layer 250 near the trenches TC in the boundary areas between the first to third sub-pixels SP1, SP2, and SP3.

The light emitting layer 350 may be disposed in the first to third light emitting areas EA1, EA2, and EA3 of the first to third sub-pixels SP1, SP2, and SP3 and in the boundary areas between the first to third sub-pixels SP1, SP2, and SP3. The light emitting layer 350 may be disposed on the first to third anode electrodes 317, 327, and 337 and the bank 300 and may also be disposed inside and above the trenches TC.

The light emitting layer 350 may be provided to emit white (W) light. To this end, the light emitting layer 350 may include a plurality of stacks that emit light of different colors.

The trenches TC are used to disconnect at least a portion of the light emitting layer 350. Because the steps are not formed on the third insulating layer 250 near the trenches TC and thus the trenches TC may be formed in a desired normal shape in the boundary areas between the first to third sub-pixels SP1, SP2, and SP3, the charge generation layer of the light emitting layer 350 is disconnected in the trenches TC. Therefore, a leakage current between the first to third sub-pixels SP1, SP2, and SP3 can be prevented or reduced. In addition, the degradation of the image quality of the organic light emitting diode display device due to the leakage current between the first to third sub-pixels SP1, SP2, and SP3 can be prevented or reduced. The trench TC and its surrounding configuration will be described in detail with reference to FIG. 4.

With reference to FIG. 4, the light emitting layer 350 may include a first stack 351, a second stack 355, and a charge generation layer CGL 353 provided between the first stack 351 and the second stack 355. The light emitting layer 350 may be disposed inside and above the trench TC. When the light emitting layer 350 is disposed inside the trench TC, at least a portion of the light emitting layer 350 may be disconnected.

The first stack 351 may be disposed on side surfaces and a lower surface of the trench TC. In this case, a portion of the first stack 351 formed on the side surfaces of the trench TC and a portion of the first stack 351 formed on the lower surface of the trench TC are not connected. In addition, the portion of the first stack 351 formed on one side surface, such as a left side surface, of the trench TC and a portion of the first stack 351 formed on the other side surface, such as a right side surface, of the trench TC are not connected. Therefore, charges may not move through the first stack 351 between the first to third sub-pixels SP1, SP2, and SP3 adjacent to each other with the trench TC interposed therebetween.

In addition, the charge generation layer 353 may be disposed on the first stack 351. In this case, the charge generation layer 353 may not extend to the inside of the trench TC and may be disposed only above the trench TC. In addition, the charge generation layer 353 may also be disposed on the first stack 351 disposed on the lower surface of the trench TC.

In this case, a portion of the charge generation layer 353 formed on one side surface, such as the left side surface, of the trench TC and a portion of the charge generation layer 353 formed on the other side, such as the right side surface, of the trench TC are not connected. Therefore, charges may not move through the charge generation layer 353 between the first to third sub-pixels SP1, SP2, and SP3 adjacent to each other with the trench TC interposed therebetween.

In addition, the second stacks 355 may be interconnected between the sub-pixels SP1, SP2, and SP3 disposed adjacent to each other with the trench TC interposed therebetween on the charge generation layer 353. Therefore, charges may move through the second stack 355 between the first to third sub-pixels SP1, SP2, and SP3 adjacent to each other with the trench TC interposed therebetween. However, by appropriately adjusting the shape of the trench TC and the deposition process of the light emitting layer 350, the second stack 355 may also be disconnected between the sub-pixels SP1, SP2, and SP3 disposed adjacent to each other with the trench TC interposed therebetween. For example, a lower portion of the second stack 355 adjacent to the charge generation layer 353 may be disconnected in the areas between the first to third sub-pixels SP1, SP2, and SP3.

An air gap AG is formed in the trench TC by the structures of the first stack 351, the charge generation layer 353, and the second stack 355. The air gap AG can be defined by the third insulating layer 250 and the light emitting layer 350. The air gap AG provided under the light emitting layer 350 can be defined by the third insulating layer 250, the first stack 351, the charge generation layer 353, and the second stack 355. The air gap AG may extend from the inside of the trench TC to the top of the trench TC.

The charge generation layer 353 has greater conductivity than the first stack 351 and the second stack 355. The charge generation layer 353 may include an n-type charge generation layer located adjacent to the first stack 351 and a p-type charge generation layer located adjacent to the second stack 355. The n-type charge generation layer may be an organic layer in which an organic host material having the electron transport ability is doped with an alkali metal, such as Li, Na, K, or Cs, or an alkaline earth metal, such as Mg, Sr, Ba, or Ra, and the p-type charge generation layer may be made of an organic host material having the hole transport ability and doped with a dopant.

As described above, because the n-type charge generation layer constituting the charge generation layer 353 may be made of a metal material, the n-type charge generation layer has greater conductivity than the first stack 351 and the second stack 355. Therefore, charges between the sub-pixels SP1, SP2, and SP3 disposed adjacent to each other are mainly moved through the charge generation layer 353.

When the first step compensation electrodes 325 partially overlapping the trenches TC and the second step compensation electrodes 334 partially overlapping the trenches TC without overlapping the first step compensation electrodes 325 are not disposed under the trenches TC, the steps ST are formed on the third insulating layer 250 near the trenches TC.

Due to the steps ST formed on the third insulating layer 250 near the trenches TC, the trenches TC are not formed in the desired normal shape, and the charge generation layer 353 of the light emitting layer 350 may not be disconnected in the trenches TC. Therefore, there are problems that a leakage current is generated between the neighboring first to third sub-pixels SP1, SP2, and SP3, and the image quality of the organic light emitting diode display device is degraded.

However, in the organic light emitting diode display device according to one embodiment of the present disclosure, by arranging the first step compensation electrodes 325 and the second step compensation electrodes 334 not overlapping the first step compensation electrodes 325 under the trenches TC formed on the boundary areas between the first to third sub-pixels SP1, SP2, and SP3, it is possible to prevent the steps from being formed on the third insulating layer near the trenches TC and disconnect the first stack 351 and the charge generation layer 353 of the light emitting layer 350 in the trenches TC when the light emitting layer 350 is formed in the trenches TC. Therefore, the leakage current between the first to third sub-pixels SP1, SP2, and SP3 can be prevented or reduced. Further, the degradation of the image quality of the organic light emitting diode display device can be prevented or reduced.

With further reference to FIGS. 2 and 3, in a top view of the organic light emitting diode display device according to one embodiment of the present disclosure, a portion of the bank 300 directly disposed on the third insulating layer 250 near the trenches TC may partially overlap the first and second step compensation electrodes 325 and 334. The first and second step compensation electrodes 325 and 334 may partially overlap a portion of the bank 300 adjacent to the trenches TC.

According to one embodiment of the present disclosure, by applying the predetermined voltage to the first step compensation electrodes 325 and the second step compensation electrodes 334 disposed in the boundary areas between the first to third sub-pixels SP1, SP2, and SP3, the charges in the charge generation layer 353 located on the bank 300 can be prevented or reduced from being guided toward the first step compensation electrodes 325 and the second step compensation electrodes 334 in the boundary areas between the first to third sub-pixels SP1, SP2, and SP3 to flow into the second stack 355 of the light emitting layer 350. Therefore, the generation of undesired light emission in the boundary areas between the first to third sub-pixels SP1, SP2, and SP3 that are non-emission areas can be prevented or reduced.

The cathode electrode 370 may be disposed on the light emitting layer 350. Like the light emitting layer 350, the cathode electrode 370 may be disposed in the emission areas EA1, EA2, and EA3 of the first to third sub-pixels SP1, SP2, and SP3 and in the boundary areas between the first to third sub-pixels SP1, SP2, and SP3. The cathode electrode 370 is a common layer and may also be formed above the bank 300 and the trench TC.

The cathode electrode 370 may be made of a semi-transparent conductive material. The cathode electrode 370 may be made of a metal material, such as magnesium (Mg), silver (Ag), or an alloy of magnesium (Mg) and silver (Ag). The cathode electrode 370 may be formed in the form of a thin film having the thickness of several nanometers to tens of nanometers. Therefore, the micro cavity effect can be obtained because light is repeatedly reflected and re-reflected between the cathode electrode 370 and the first to third reflective electrodes 317, 327, and 337.

According to one embodiment of the present disclosure, because a first distance between the first reflective electrode 311 and the cathode electrode 370 in the first sub-pixel SP1, a second distance between the second reflective electrode 323 and the cathode electrode 370 in the second sub-pixel SP2, and a third distance between the third reflective electrode 335 and the cathode electrode 370 in the third sub-pixel SP3 may all be configured differently, light extraction efficiency of light of different colors, such as red, green, and blue light, in the sub-pixels SP1, SP2, and SP3 can be increased by the micro cavity effect.

The encapsulation layer 400 is formed on the cathode electrode 370 to prevent the permeation of external moisture into the light emitting layer 350. The encapsulation layer 400 may include a first inorganic encapsulation layer 410 disposed on the cathode electrode 370, an organic encapsulation layer 430 disposed on the first inorganic encapsulation layer 410, and a second inorganic encapsulation layer 450 disposed on the organic encapsulation layer 430. The first and second inorganic encapsulation layers 410 and 450 may each be selected from aluminum oxide (AlₓO_{y}), silicon oxide (SiOₓ), silicon nitride (SiNₓ), silicon oxynitride (SiON), etc.

When the steps occurs on the third insulating layer 250 near the trenches TC, cracks, such as seams, of the encapsulation layer 400 may occur on the trenches TC. Thus, due to moisture permeation, the reliability of the organic light emitting diode display device can be degraded.

According to one embodiment of the present disclosure, Because the steps do not occur on the third insulating layer 250 near the trenches TC, the occurrence of cracks, such as seams, of the encapsulation layer 400 on the trenches TC can be prevented or reduced, thereby improving the reliability of the organic light emitting diode display device.

The first to third color filters 510, 530, and 550 may be disposed on the encapsulation layer 400. The red color filter 510 overlapping the first emission area EA1 may be provided in the first sub-pixel SP1, the green color filter 530 overlapping the second emission area EA2 may be provided in the second sub-pixel SP2, and the blue color filter 550 overlapping the third emission area EA3 may be provided in the third sub-pixel SP3. The first color filter 510 may be a red color filter that emits light of red, the second color filter 530 may be a green color filter that emits light of green, and the third color filter 550 may be a blue color filter that emits light of blue.

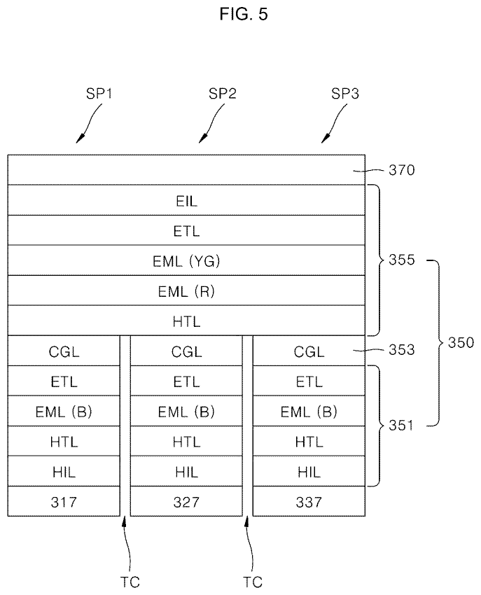

FIG. 5 is a schematic cross-sectional view of light emitting layers disposed in sub-pixels according to one embodiment of the present disclosure.

With reference to FIG. 5, the first anode electrode 317 is disposed in the first sub-pixel SP1, the second anode electrode 327 is disposed in the second sub-pixel SP2, and the third anode electrode 337 is disposed in the third sub-pixel SP3. The light emitting layer 350 is disposed on the first to third anode electrodes 317, 327, and 337. The light emitting layer 350 includes the first stack 351, the second stack 355, and the charge generation layer CGL 353.

The first stack 351 may be formed in a structure in which a hole injecting layer HIL, a hole transporting layer HTL, a blue emitting layer EML (B), and an electron transporting layer ETL are stacked sequentially. The first stack 351 may be disconnected in the trenches TC disposed in the boundary areas between the sub-pixels SP1, SP2, and SP3.

The charge generation layer CGL 353 serves to supply charges to the first stack 351 and the second stack 355. The charge generation layer CGL 353 may include an n-type charge generation layer for supplying electrons to the first stack 351 and a p-type charge generation layer for supplying holes to the second stack 355. As described above, the n-type charge generation layer may include a metal material as a dopant. The charge generation layer 720 may be disconnected in the trenches TC disposed in the boundary areas between the sub-pixels SP1, SP2, and SP3.

The second stack 355 may be provided on the charge generation layer CGL 353 and formed in a structure in which the hole transporting layer HTL, a red emitting layer EML (R), a yellow green emitting layer EML (YG), the electron transporting layer ETL, and the electron injecting layer EIL are stacked sequentially. The stacking order of the red emitting layer EML (R) and the yellow green emitting layer EML (YG) may be changed.

The second stack 355 may be disposed to be connected between the sub-pixels SP1, SP2, and SP3. However, as described above, the lower portion of the second stack 355 may be disconnected in the boundary areas between the sub-pixels P1, P2, and P3, for example, the trench TC areas. For example, the hole transporting layer HTL of the second stack 355 may be disconnected, or the hole transporting layer HTL and the red emitting layer EML (R) that form the second stack 355 may be disconnected. For example, the hole transporting layer HTL, the red emitting layer EML (R), and the yellow green emitting layer EML (YG) of the second stack 355 may be disconnected.

The cathode electrode 370 is disposed on the light emitting layer 350. The cathode electrode 370 may be formed to be connected between the sub-pixels SP1, SP2, and SP3. The light emitting layer 350 of FIG. 5 emits white light in a combination of the blue emitting layer EML (B) of the first stack 351 and the red emitting layer EML (R) and the yellow green emitting layer EML (YG) of the second stack 355.

In one embodiment, the second stack 355 may include only the yellow green emitting layer EML (YG). In this case, white light is emitted in a combination of the blue emitting layer EML (B) of the first stack 351 and the yellow green emitting layer EML (YG) of the second stack 355.

In one embodiment, the green emitting layer EML (G) may be formed instead of the yellow green emitting layer EML (YG) of the second stack 355. In this case, the light emitting layer 350 emits white light in a combination of the blue emitting layer EML (B) of the first stack 351 and the red emitting layer EML (R) and green emitting layer EML (G) of the second stack 355.

In one embodiment, the first stack 351 may include the red emitting layer EML (R) and the yellow green emitting layer EML (YG), and the second stack 355 may include the blue emitting layer EML (B). In one embodiment, the first stack 351 may include the red emitting layer EML (R) and the green emitting layer EML (G), and the second stack 355 may include the blue emitting layer EML (B).

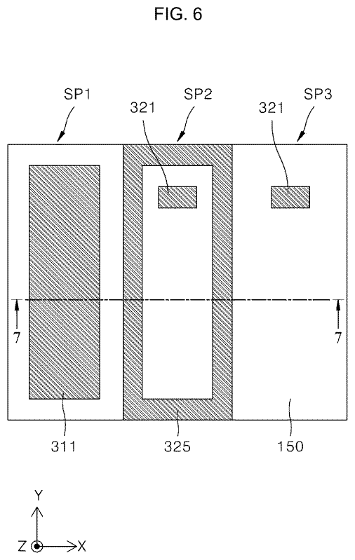

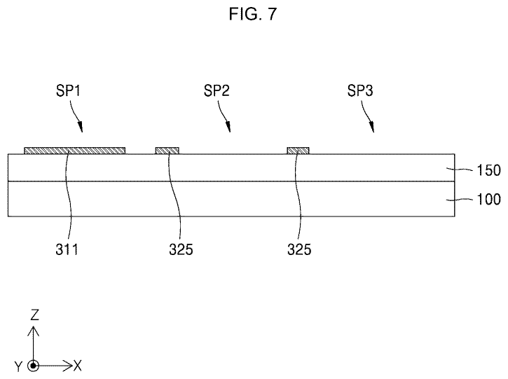

FIGS. 6 to 15 are schematic views for describing a method of manufacturing an organic light emitting diode display device according to one embodiment of the present disclosure, in which FIGS. 6, 8, 10, 12, and 14 are plan views, and FIGS. 7, 9, 11, 13, and 15 are cross-sectional views.

With reference to FIGS. 6 and 7, the first insulating layer 150 may be formed on the substrate 100. The first insulating layer 150 may cover transistors including driving transistors TR, various signal lines, capacitors, etc. that are disposed on the substrate 100. An additional insulating layer and an additional conductive pattern may be disposed between the substrate 100 and the first insulating layer 150.

The first reflective electrode 311, the first contact electrodes 321, and the first step compensation electrodes 325 may be disposed on the first insulating layer 150. The first reflective electrode 311, the first contact electrodes 321, and the first step compensation electrodes 325 may be formed of the same thickness and the same material by the same process.

The first reflective electrode 311 may be formed in the first sub-pixel SP1, and the first step compensation electrodes 325 may be formed in the second sub-pixel SP2. The first contact electrode 321 may be formed in each of the second sub-pixel SP2 and the third sub-pixel SP3.

In a plan view, the first step compensation electrodes 325 may be disposed at the left and right sides of the second sub-pixel SP2, and the first step compensation electrodes 325 may be connected at the upper and lower sides of the second sub-pixel SP2. In one embodiment, the first step compensation electrodes 325 may be connected at the upper side or lower side of the second sub-pixel SP2. In one embodiment, the first step compensation electrodes 325 may not be connected at the upper and lower sides of the second sub-pixel SP2.

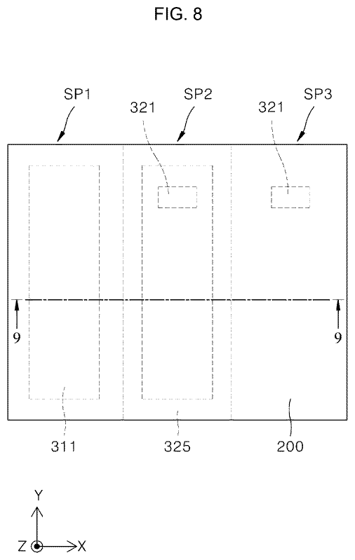

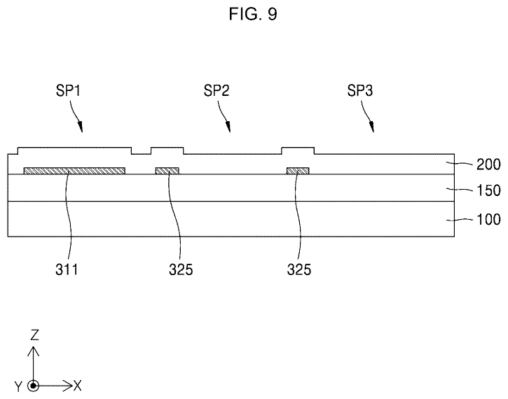

With reference to FIGS. 8 and 9, the second insulating layer 200 may be formed on the first insulating layer 150. The second insulating layer 200 may be made of, for example, an inorganic material. An upper surface of the second insulating layer 200 may have steps due to the first reflective electrode 311, the first contact electrodes 321, and the first step compensation electrodes 325.

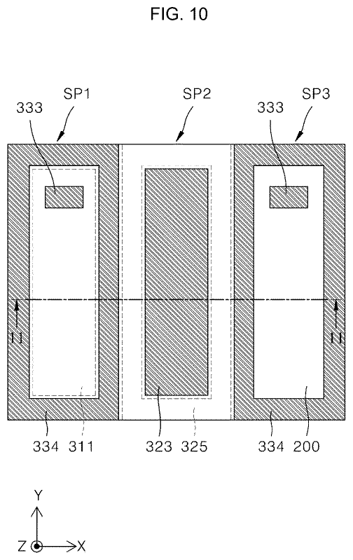

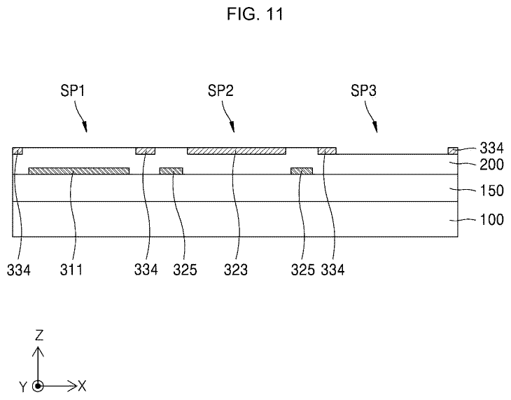

With reference to FIGS. 10 and 11, the second reflective electrode 323, the second contact electrodes 333, and the second step compensation electrodes 334 may be formed on the second insulating layer 200. The second reflective electrode 323, the second contact electrodes 333, and the second step compensation electrodes 334 may be formed of the same thickness and the same material by the same process.

The second reflective electrode 323 may be formed in the second sub-pixel SP2, and the first step compensation electrodes 325 may be formed in the first sub-pixel SP1 and the third sub-pixel SP3. The second contact electrode 333 may be formed in each of the first sub-pixel SP1 and the third sub-pixel SP3.

In a plan view, the second step compensation electrodes 334 may be disposed at the left and right sides of the first sub-pixel SP1 and at the left and right sides of the third sub-pixel SP3. In a plan view, the second step compensation electrodes 334 may be connected at the upper and lower sides of the first sub-pixel SP1 and at the upper and lower sides of the third sub-pixel SP3. In one embodiment, the second step compensation electrodes 334 may be connected at the upper sides or lower sides of the first sub-pixel SP1 and the third sub-pixel SP3. In one embodiment, the second step compensation electrodes 334 may not be connected at the upper and lower sides of the first sub-pixel SP1 and the third sub-pixel SP3.

In a plan view, the second step compensation electrodes 334 may be formed on the second insulating layer 200 so as not to overlap the first reflective electrode 311 and the first step compensation electrodes 325. The second step compensation electrodes 323 may be formed on the second insulating layer 200 so as not to overlap the first reflective electrode and the first step compensation electrodes 325.

In addition, the thickness of the second reflective electrode 323 and the thickness of the second step compensation electrodes 334 may be formed to be the same as the thickness of the first reflective electrode 311 and the thicknesses of the first step compensation electrodes 325.

Therefore, the second step compensation electrode 334 and the second insulating layer 200 may form or provide flat surfaces in the boundary area between the first sub-pixel SP1 and the second sub-pixel SP2 and in the boundary area between the first sub-pixel SP1 and the second sub-pixel SP2.

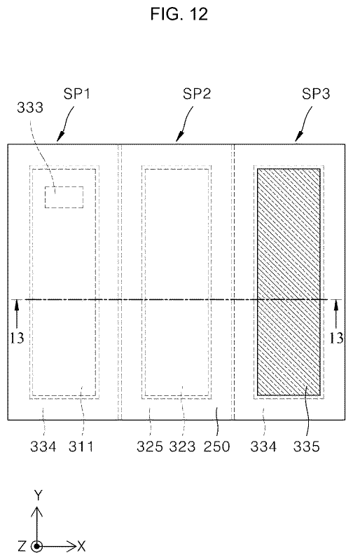

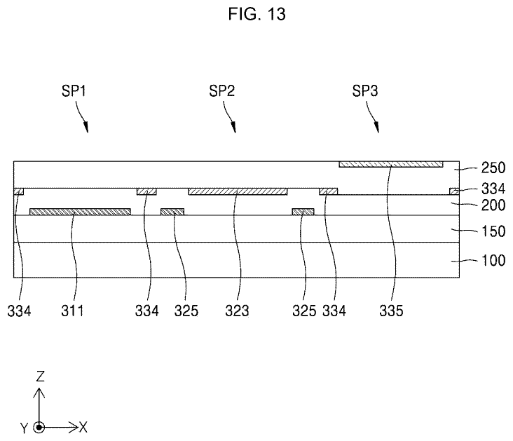

With reference to FIGS. 12 and 13, the third insulating layer 250 may be formed on the second insulating layer 200. The third insulating layer 250 may be made of, for example, an inorganic material. The third insulating layer 250 may have a flat surface in the boundary area between the first sub-pixel SP1 and the second sub-pixel SP2 and in the boundary area between the first sub-pixel SP1 and the second sub-pixel SP2.

The third reflective electrode 335 may be disposed on the third insulating layer 250. In a plan view, the third reflective electrode 335 may be formed on the third insulating layer 250 so as not to overlap the second step compensation electrodes 334.

In addition, the thickness of the third reflective electrode 335 may be formed to be the same as the thickness of the first reflective electrode 311 and the thicknesses of the first step compensation electrodes 325. The thickness of the third reflective electrode 335 may be formed to be the same as the thickness of the second reflective electrode 323 and the thickness of the second step compensation electrodes 334.

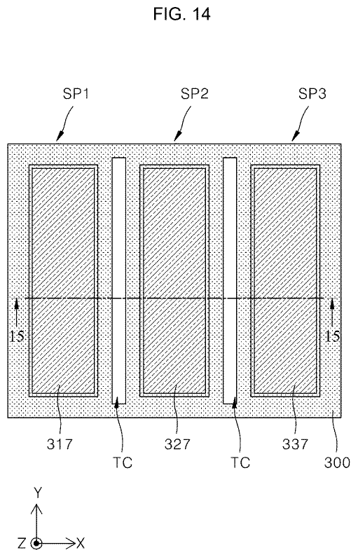

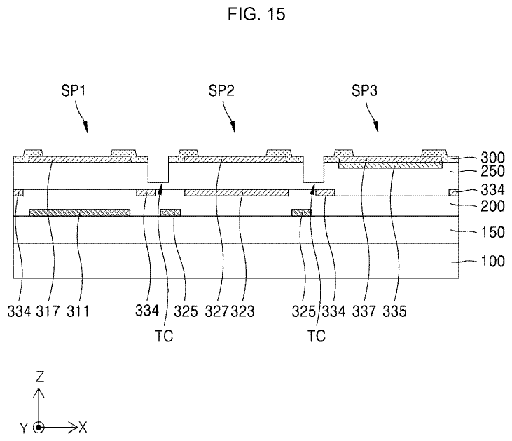

With reference to FIGS. 14 and 15, the first anode electrode 317, the second anode electrode 327, and the third anode electrode 337 may be formed on the third insulating layer 250. The first anode electrode 317 may be disposed in the first sub-pixel SP1, the second anode electrode 327 may be formed in the second sub-pixel SP2, and the third anode electrode 337 may be disposed in the third sub-pixel SP3. The third anode electrode 337 may be disposed directly on the third reflective electrode 335. The first to third anode electrodes 317, 327, and 337 may be formed of the same thickness and the same material by the same process.

Next, the bank 300 may be formed to cover an edge area of the first anode electrode 317, an edge area of the second anode electrode 327, and an edge area of the third anode electrode 337 on the third insulating layer 250.

Then, the trenches TC may be formed in the boundary area between the first sub-pixel SP1 and the second sub-pixel SP2 and in the boundary area between the first sub-pixel SP1 and the second sub-pixel SP2. The trenches TC may be formed by removing a partial area of the bank 300 and a partial area of the third insulating layer 250 in the boundary area between the first sub-pixel SP1 and the second sub-pixel SP2 and in the boundary area between the first sub-pixel SP1 and the second sub-pixel SP2. Because the third insulating layer 250 may have the flat surface in the boundary area between the first sub-pixel SP1 and the second sub-pixel SP2 and in the boundary area between the first sub-pixel SP1 and the second sub-pixel SP2, the trenches TC may be formed in the desired normal shape.

In this case, the trenches TC may partially overlap the first and second step compensation electrodes 325 and 334. A portion of the bank 300 directly disposed on the third insulating layer 250 near the trenches TC may partially overlap the first and second step compensation electrodes 325 and 334.

Hereinafter, a connection structure for allowing the first and second step compensation electrodes 325 and 334 to maintain a lower voltage than the first to third anode electrodes 317, 327, and 337 will be described.

FIG. 16 is a schematic plan view showing the pixel of the organic light emitting diode display device according to one embodiment of the present disclosure.

With reference to FIG. 16, the substrate 100 includes an active area AA including the first sub-pixel SP1, the second sub-pixel SP2, and the third sub-pixel SP3, and a non-active area NAA adjacent to the active area AA. A cathode contact line 630 may be provided in the non-active area NAA.

For example, the plurality of sub-pixels SP1, SP2, and SP3 arranged in the X-axis and Y-axis directions are provided on the substrate 100. For example, the first sub-pixel SP1, the second sub-pixel SP2, and the third sub-pixel SP3 may be sequentially and repeatedly arranged in the X-axis direction on the substrate 100. In addition, the first sub-pixel SP1, the second sub-pixel SP2, and the third sub-pixel SP3 may be repeatedly arranged in the Y direction on the substrate 100. The plurality of first sub-pixels SP1 may form a first column in the Y direction, the plurality of second sub-pixels SP2 form a second column in the Y direction, and the plurality of third sub-pixels SP3 may form a third column. For example, the first sub-pixel SP1 may emit light of red, the second sub-pixel SP2 may emit light of green, and the third sub-pixel SP3 may emit light of blue.

The first step compensation electrodes 325 may extend in the Y direction and may be disposed in the second columns of the second sub-pixels SP2, and the second step compensation electrodes 334 may extend in the Y direction and may be disposed in the first columns of the first sub-pixels SP1 and the third columns of the third sub-pixels SP3. The first step compensation electrode 325 and the second step compensation electrodes 334 may extend from the active area AA to the non-active area NAA. The first step compensation electrode 325 and the second step compensation electrodes 334 may extend under the cathode contact line 630 provided in the non-active area NAA and may be electrically connected to the cathode contact line 630.

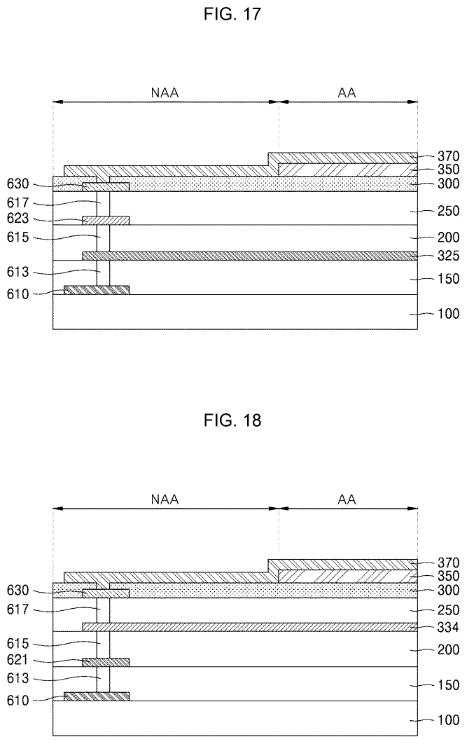

FIG. 17 is a schematic cross-sectional view showing the organic light emitting diode display device according to one embodiment of the present disclosure, which is a cross-sectional view along line 17-17 in FIG. 16.

With reference to FIG. 17, a cathode line 610 and the first insulating layer 150 covering the cathode line 610 may be disposed in the non-active area NAA on the substrate 100. The cathode line 610 may be, for example, a ground line. The first step compensation electrode 325 may be disposed on the first insulating layer 150. The first step compensation electrode 325 may extend from the active area AA to the non-active area NAA and may be electrically connected to the cathode line 610 through the contact via 613 passing through the first insulating layer 150. Therefore, a predetermined first voltage provided to the cathode line 610 may be applied to the first step compensation electrode 325.

The second insulating layer 200 may cover the first step compensation electrode 325 and may be disposed on the first insulating layer 150. A contact electrode 623 may be disposed on the second insulating layer 200 in the non-active area NAA. The contact electrode 623 may be electrically connected to the first step compensation electrode 325 through a contact via 615 passing through the second insulating layer 200.

The third insulating layer 250 may cover the contact electrode 623 and may be disposed on the second insulating layer 200. The cathode contact line 630 may be disposed on the third insulating layer 250 in the non-active area NAA. The cathode contact line 630 may be electrically connected to the contact electrode 623 through a contact via 617 passing through the third insulating layer 250.

The bank 300 may be disposed on the third insulating layer 250, and the light emitting layer 350 may be disposed on the bank 300 in the active area AA. The cathode electrode 370 may be disposed on the light emitting layer 350, and the cathode electrode 370 may extend from the active area AA to the non-active area NAA. In the non-active area NAA, the cathode electrode 370 may extend the contact holes passing through the bank 300 and may be electrically connected to the cathode contact line 630.

The cathode electrode 370 may be electrically connected to the cathode line 610 through the contact vias 613, 615, and 617, the contact electrode 623, and the first step compensation electrode 325. Therefore, the predetermined first voltage provided to the cathode line 610 may be applied to the cathode electrode 370.

In the non-active area NAA, the cathode electrode 370 and the first step compensation electrode 325 may be electrically connected. Therefore, the same voltage as the cathode electrode 370 may be applied to the first step compensation electrode 325.

FIG. 18 is a schematic cross-sectional view showing the organic light emitting diode display device according to one embodiment of the present disclosure, which is a cross-sectional view along line 18-18 in FIG. 16.

With reference to FIG. 18, the cathode line 610 and the first insulating layer 150 covering the cathode line 610 may be disposed in the non-active area NAA on the substrate 100. The contact electrode 621 disposed on the first insulating layer 150 in the non-active area NAA may be electrically connected to the cathode line 610 through the contact via 613 passing through the first insulating layer 150.

The second insulating layer 200 may cover the contact electrode 621 and may be disposed on the first insulating layer 150. The second step compensation electrode 334 disposed on the second insulating layer 200 may extend from the active area AA to the non-active area NAA and may be electrically connected to the cathode line 621 through the contact via 615 passing through the second insulating layer 200. The second step compensation electrode 334 may be electrically connected to the cathode line 610 through the contact vias 613 and 615 and the contact electrode 621. Therefore, the predetermined first voltage provided to the cathode line 610 may be applied to the second step compensation electrode 334.

The third insulating layer 250 may cover the second step compensation electrode 334 and may be disposed on the second insulating layer 200. The cathode contact electrode 630 disposed on the third insulating layer 250 in the non-active area NAA may be electrically connected to the second step compensation electrode 334 through the contact via 617 passing through the third insulating layer 250.

The bank 300 may be disposed on the third insulating layer 250, and the light emitting layer 350 may be disposed on the bank 300 in the active area AA. The cathode electrode 370 may be disposed on the light emitting layer 350 may extend from the active area AA to the non-active area NAA. In the non-active area NAA, the cathode electrode 370 may extend the contact holes passing through the bank 300 and may be electrically connected to the cathode contact line 630.

The cathode electrode 370 may be electrically connected to the cathode line 610 through the contact vias 613, 615, and 617, the contact electrode 621, and the second step compensation electrode 334. Therefore, the predetermined first voltage provided to the cathode line 610 may be applied to the cathode electrode 370.

In the non-active area NAA, the cathode electrode 370 and the second step compensation electrode 334 may be electrically connected. Therefore, the same voltage as the cathode electrode 370 may be applied to the second step compensation electrode 334. In the present embodiment, the first step compensation electrode 325 and the second step compensation electrode 334 may be electrically connected to the cathode line 610 through which the predetermined voltage is applied to the cathode electrode 370.

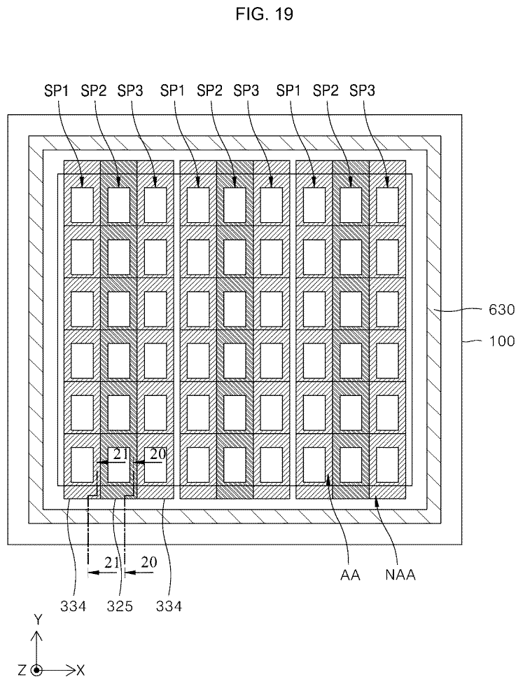

FIG. 19 is a schematic plan view showing the organic light emitting diode display device according to one embodiment of the present disclosure. When describing the organic light emitting diode display device of FIG. 19, differences from the organic light emitting diode display device of FIG. 16 will be mainly described.

With reference to FIG. 19, the substrate 100 includes the active area AA including the first sub-pixel SP1, the second sub-pixel SP2, and the third sub-pixel SP3, and the non-active area NAA adjacent to the active area AA. The cathode contact line 630 may be provided in the non-active area NAA.

The first step compensation electrodes 325 may extend in the Y direction and may be disposed in the second columns of the second sub-pixels SP2, and the second step compensation electrodes 334 may extend in the Y direction and may be disposed in the first columns of the first sub-pixels SP1 and the third columns of the third sub-pixels SP3. The first step compensation electrode 325 and the second step compensation electrodes 334 may extend from the active area AA to the non-active area NAA. However, unlike FIG. 16, the first step compensation electrode 325 and the second step compensation electrodes 334 does not extend to the cathode contact line 630 and may be electrically connected to an external low potential voltage line in the non-active area NAA.

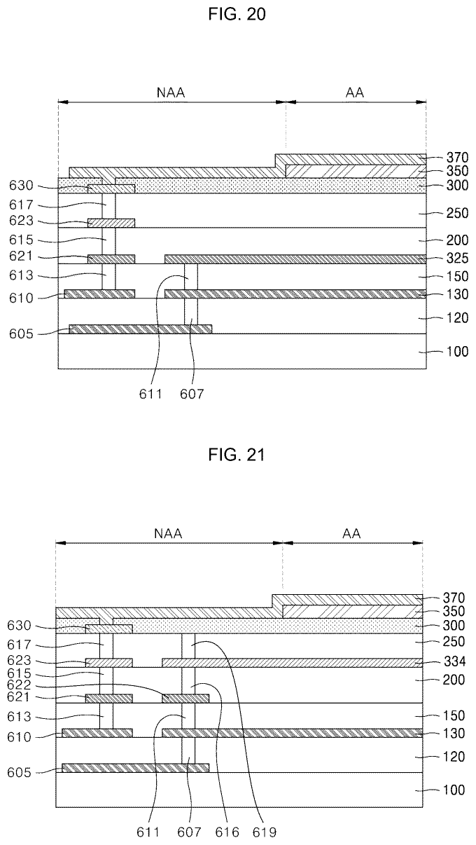

FIG. 20 is a schematic cross-sectional view showing the organic light emitting diode display device according to one embodiment of the present disclosure, which is a cross-sectional view along line 20-20 in FIG. 19. When describing the organic light emitting diode display device of FIG. 20, differences from the organic light emitting diode display device of FIG. 17 will be mainly described.

With reference to FIG. 20, the external low potential voltage line 605 may be disposed in the non-active area NAA on the substrate 100. A buffer layer 120 covering the external low potential voltage line 605 may be disposed on the substrate 100. An internal low potential voltage line 130 may be disposed on the buffer layer 120 in the active area AA. The internal low potential voltage line 130 may be electrically connected to the external low potential voltage line 605 through a contact via 607 extending to the non-active area NAA and passing through the buffer layer 120. In addition, the cathode line 610 may be disposed on the buffer layer 120 in the non-active area NAA.

The external low potential voltage wiring 605 may be a line through which a higher potential voltage than the cathode line 610 is supplied. In addition, the external low potential voltage line 605 may be a line through which a voltage of a lower potential than the first to third anode electrodes 317, 327, and 337 is supplied.

The first insulating layer 150 covering the cathode line 610 may be disposed. The first step compensation electrode 325 and the contact electrode 621 may be disposed on the first insulating layer 150. The first step compensation electrode 325 may extend from the active area AA to the non-active area NAA and may be electrically connected to the internal low potential voltage line 130 through the contact via 611 passing through the first insulating layer 150. Therefore, the first step compensation electrode 325 may be electrically connected to the external low potential voltage line 605 through the contact vias 607 and 611 and the internal low potential voltage line 130. The contact electrode 621 may be electrically connected to the cathode line 610 through the contact via 613 passing through the first insulating layer 150.

The contact electrode 623 disposed on the second insulating layer 200 in the non-active area NAA may be electrically connected to the cathode line 621 through the contact via 615 passing through the second insulating layer 200.

The cathode contact electrode 630 disposed on the third insulating layer 250 in the non-active area NAA may be electrically connected to the contact electrode 623 through the contact via 617 passing through the third insulating layer 250. In the non-active area NAA, the cathode electrode 370 may extend the contact holes passing through the bank 300 and may be electrically connected to the cathode contact line 630. The cathode electrode 370 may be electrically connected to the cathode line 610 through the contact vias 613, 615, and 617 and the contact electrodes 621 and 623.

FIG. 21 is a schematic cross-sectional view showing the organic light emitting diode display device according to one embodiment of the present disclosure, which is a cross-sectional view along line 21-21 in FIG. 19. When describing the organic light emitting diode display device of FIG. 21, differences from the organic light emitting diode display device of FIG. 18 will be mainly described.

With reference to FIG. 21, the external low potential voltage line 605 may be disposed in the non-active area NAA on the substrate 100. The buffer layer 120 covering the external low potential voltage line 605 may be disposed on the substrate 100. The internal low potential voltage line 130 disposed on the buffer layer 120 in the active area AA may be electrically connected to the external low potential voltage line 605 through the contact via 607 extending to the non-active area NAA and passing through the buffer layer 120. In addition, the cathode line 610 may be disposed on the buffer layer 120 in the non-active area NAA.

The external low potential voltage line 605 may be a line having a higher potential than the cathode line 610. In addition, the external low potential voltage line 605 may be a line having a lower potential than the first to third anode electrodes 317, 327, and 337.

The first insulating layer 150 covering the cathode line 610 may be disposed. The contact electrodes 621 and 622 may be disposed on the first insulating layer 150 in the non-active area NAA. The contact electrode 622 may be electrically connected to the internal low potential voltage line 130 through the contact via 611 passing through the first insulating layer 150. The contact electrode 621 may be electrically connected to the cathode line 610 through the contact via 613 passing through the first insulating layer 150.

The contact electrode 623 and the second step compensation electrode 334 may be disposed on the second insulating layer 200 covering the contact electrodes 621 and 622. The contact electrode 623 disposed on the second insulating layer 200 in the non-active area NAA may be electrically connected to the cathode line 621 through the contact via 615 passing through the second insulating layer 200.

The second step compensation electrode 334 may extend from the active area AA to the non-active area NAA and may be electrically connected to the cathode line 622 through the contact via 616 passing through the second insulating layer 200. Therefore, the second step compensation electrode 334 may be electrically connected to the external low potential voltage line 605 through the contact vias 607, 611, and 616, the contact electrode 622, and the internal low potential voltage line 130.

The contact electrode 623 disposed on the second insulating layer 200 in the non-active area NAA may be electrically connected to the cathode line 614 through the contact via 615 passing through the second insulating layer 200. The cathode contact electrode 630 disposed on the third insulating layer 250 in the non-active area NAA may be electrically connected to the contact electrode 623 through the contact via 617 passing through the third insulating layer 250.

In the non-active area NAA, the cathode electrode 370 may extend the contact holes passing through the bank 300 and may be electrically connected to the cathode contact line 630. The cathode electrode 370 may be electrically connected to the cathode line 610 through the contact vias 613, 615, and 617 and the contact electrodes 621 and 623.

In the present example embodiment, the first step compensation electrode 325 and the second step compensation electrode 334 may be electrically connected to the external low potential voltage line 605 for providing the predetermined voltage to the internal low potential voltage line 130.

With reference to FIGS. 16 to 21, it has been described that the first step compensation electrodes 325 and the second step compensation electrodes 334 are connected to the same line to have the same voltage, but in one embodiment, the first step compensation electrodes 325 and the second step compensation electrodes 334 may be connected to different lines to have different voltages. For example, the first step compensation electrodes 325 may be electrically connected to the cathode line 610, and the second step compensation electrodes 334 may be electrically connected to the external low potential voltage line 605.

FIGS. 22 to 24 show a head mounted display device according to one embodiment of the present disclosure.

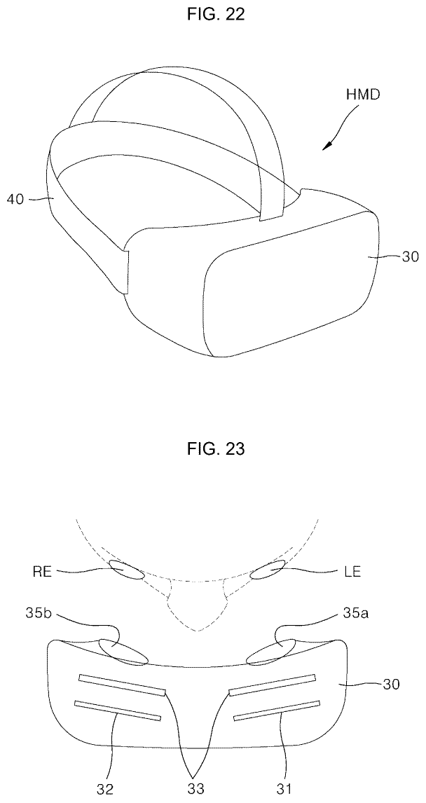

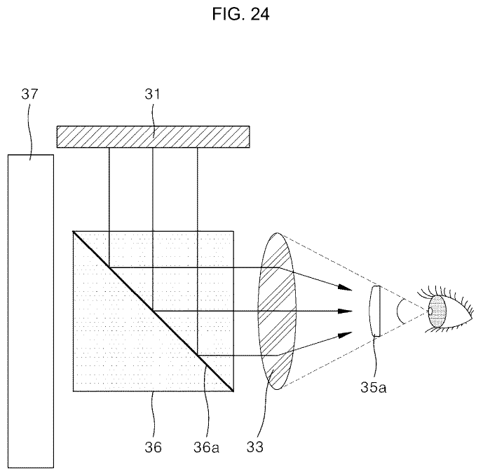

FIG. 22 is a schematic perspective view of a head mounted display device according to one embodiment of the present disclosure, FIG. 23 is a view schematically showing a head mounted display device in which virtual reality (VR) is implemented, and FIG. 24 is a view schematically showing a head mounted display device in which augmented reality (AR) is implemented.

With reference to FIG. 22, the head mounted display device according to one embodiment of the present disclosure includes a storage case 30 and a head mounting band 40. The storage case 30 stores components, such as a display device, a lens array, and an eyepiece, therein.

The head mounting band 40 is fixed to the storage case 30. An example in which the head mounting band 40 is formed to surround an upper surface and side surfaces of the user's head, but the present disclosure is not limited thereto. The head mounting band 40 is used to fix the head mounted display to the user's head and may be replaced with a structure in the form of a glasses frame or a helmet.

With reference to FIG. 23, the head mounted display device in which the VR is implemented includes a left-eye display device 31, a right-eye display device 32, a lens array 33, a left-eye eyepiece 35a, and a right-eye eyepiece 35b. The left-eye display device 31, the right-eye display device 32, the lens array 33, the left-eye eyepiece 35a, and right-eye eyepiece 35b are stored in the storage case 30.

The left-eye display device 31 and the right-eye display device 32 may display the same image, and in this case, the user may view 2D images. Alternatively, the left-eye display device 31 may display left-eye images, and the right-eye display device 32 may display right-eye images, and in this case, the user may view three-dimensional images. The left-eye display device 31 and the right-eye display device 32 may each be provided as the above-described organic light emitting display device according to FIGS. 1 to 21.

The lens array 33 may be spaced apart from each of the left-eye eyepiece 35a and the left-eye display device 31 and provided between the left-eye eyepiece 35a and the left-eye display device 31. For example, the lens array 33 may be located in front of the left-eye eyepiece 35a and behind the left-eye display device 31. In addition, the lens array 33 may be spaced apart from each of the right-eye eyepiece 35b and the right-eye display device 32 and provided between the right-eye eyepiece 35b and the right-eye display device 32. For example, the lens array 33 may be located in front of the right-eye eyepiece 35b and behind the right-eye display device 32.

The lens array 33 may be a micro lens array. The lens array 33 may be replaced with a pin hole array. Due to the lens array 33, enlarged images displayed on the left-eye display device 31 and the right-eye display device 32 may be enlarged and visible to the user. The user's left eye LE may be located behind the left-eye eyepiece 35a, and the user's right eye RE may be located behind the right-eye eyepiece 35b.

With reference to FIG. 24, the head mounted display device in which the AR is implemented includes the left-eye display device 31, the lens array 33, the left-eye eyepiece 35a, a transmission reflector 36, and a transmission window 37. In FIG. 24, only a configuration of the left-eye side is shown for convenience, and a configuration of the right-eye side is also the same or similar to that of the left-eye side.

The left-eye display device 31, the lens array 33, the left-eye eyepiece 35a, the transmission reflector 36, and the transmission window 37 are stored in the storage case 30. The left-eye display device 31 may be disposed at one side, for example, an upper side of the transmission reflector 36 without blocking the transmission window 37. Therefore, the left-eye display device 31 may provide images to the transmission reflector 36 without blocking an external background visible through the transmission window 37.

The left-eye display device 31 may be provided as the above-described organic light emitting diode display device according to FIGS. 1 to 21.

The lens array 33 may be provided between the left-eye eyepiece 35a and the transmission reflector 36. The user's left eye is located behind the left-eye eyepiece 35a.

The transmission reflector 36 is disposed between the lens array 33 and the transmission window 37. The transmission reflector 36 may include a reflective surface 36a for transmitting some of light and reflecting others of the light. The reflective surface 36a includes a semi-transmissive metal film. The semi-transmissive metal film may be made of a semi-transmissive metal material, such as magnesium (Mg), silver (Ag), or an alloy of magnesium (Mg) and silver (Ag). The reflective surface 36a is formed so that the images displayed on the left-eye display device 31 proceed to the lens array 33.

Therefore, the user may view both the external background visible through the transparent window 37 and the images displayed by the left-eye display device 31. For example, because the user may view the real background and the virtual image as one image by allowing the real background and the virtual image to overlap each other, the AR can be implemented.

An organic light emitting diode display device and a head mounted display device according to embodiments of the present disclosure may be described as follows.

An organic light emitting diode display device according to one embodiment of the present disclosure may include an active area having a first sub-pixel, a second sub-pixel, and a third sub-pixel, and a non-active area adjacent to the active area. The organic light emitting diode display device may comprise a substrate; a first insulating layer on the substrate; a first reflective electrode on the first insulating layer in the first sub-pixel; a first step compensation electrodes on the first insulating layer at a first boundary area between the first and second sub-pixels and at a first boundary area between the second and third subpixels; a second insulating layer on the first insulating layer, and covering the first reflective electrode and the first step compensation electrodes; a second reflective electrode on the second insulating layer in the second sub-pixel; second step compensation electrodes on the first insulating layer at the first boundary area and at the second boundary area; a third insulating layer on the second insulating layer, and covering the second reflective electrode and the second step compensation electrodes; and a third reflective electrode on the third insulating layer in the third sub-pixel, wherein trenches are defined in the third insulating layer respectively at the first and second boundary areas; wherein each one of the first step compensation electrodes partially overlap a respective one the trenches in a plan view, and wherein each one of the second step compensation electrodes partially overlap a respective one of the trenches in a plan view.

According to one embodiment of the present disclosure, in the plan view of the organic light emitting diode display device, the second step compensation electrodes may not overlap the first step compensation electrodes.

According to one embodiment of the present disclosure, in the plan view of the organic light emitting diode display device, the first step compensation electrodes do not overlap the second reflective electrode, and the second step compensation electrodes may not overlap the first reflective electrode and the third reflective electrode.

According to one embodiment of the present disclosure, the first step compensation electrodes may be spaced apart from the first reflective electrode in the plan view, and the second step compensation electrodes may be spaced apart from the second reflective electrode in the plan view.

According to one embodiment of the present disclosure, the first step compensation electrodes, the first reflective electrode, the second step compensation electrodes, and the second reflective electrode may have a same thickness.

According to one embodiment of the present disclosure, the first and second step compensation electrodes may extend longer than the trenches in a length direction of the trenches.

According to one embodiment of the present disclosure, the first and second step compensation electrodes may extend from the active area to the non-active area, and a predetermined voltage may be applied to the first and second step compensation electrodes.

According to one embodiment of the present disclosure, a cathode line through which the predetermined voltage is applied to a cathode electrode may be provided in the non-active area, and the first and second step compensation electrodes may be electrically connected to the cathode line in the non-active area.

According to one embodiment of the present disclosure, an external low potential voltage line may be provided in the non-active area, and the first and second step compensation electrodes may be electrically connected to the external low potential voltage line in the non-active area.

According to one embodiment of the present disclosure, a first voltage may be applied to the first step compensation electrodes, and a second voltage different from the first voltage may be applied to the second step compensation electrodes.

According to one embodiment of the present disclosure, the organic light emitting diode display device may further include a first anode electrode on the third insulating layer in the first sub-pixel, a second anode electrode on the third insulating layer in the second sub-pixel, a third anode electrode on the third reflective electrode in the third sub-pixel, and a bank on the third insulating layer. The bank may cover edge areas of the first, second, and third anode electrodes. The first and second step compensation electrodes may partially overlap a portion of the bank adjacent to the trenches.

According to one embodiment of the present disclosure, in a top view of the organic light emitting diode display device, the first step compensation electrodes do not overlap the second anode electrode, and the second step compensation electrodes may not overlap the first and third anode electrodes.

The first reflective electrode may be absent in the second and third sub-pixels, the second reflective electrode may be absent in the first and third sub-pixels, and the third reflective electrode may be absent in the first and second sub-pixels.

The first step compensation electrodes and the first reflective electrode may have a first thickness, and the second step compensation electrodes and the second reflective electrode may have a second thickness.

The first step compensation electrodes may be coplanar with the first reflective electrode, and the second step compensation electrodes may be coplanar with the second reflective electrode.

A head mounted display device according to one embodiment of the present disclosure may include a left-eye eyepiece and a right-eye eyepiece, a left-eye display device and a right-eye display device that provide an image to the left-eye eyepiece and the right-eye eyepiece, in which each of the left-eye display device and the right-eye display device may respectively include the organic light emitting diode display device according to one embodiment of the present disclosure.

An organic light emitting diode display device according to one embodiment of the present disclosure may include an active area having a first sub-pixel, a second sub-pixel, and a third sub-pixel, and a non-active area adjacent to the active area. The organic light emitting diode display device may comprise a substrate; a first insulating layer on the substrate; a first reflective electrode on the first insulating layer in the first sub-pixel; a first step compensation electrodes on the first insulating layer at a first boundary area between the first and second sub-pixels and at a first boundary area between the second and third subpixels; a second insulating layer on the first insulating layer, and covering the first reflective electrode and the first step compensation electrodes; a second reflective electrode on the second insulating layer in the second sub-pixel; second step compensation electrodes on the first insulating layer at the first boundary area and at the second boundary area; a third insulating layer on the second insulating layer, and covering the second reflective electrode and the second step compensation electrodes; and a third reflective electrode on the third insulating layer in the third sub-pixel. Trenches may be defined in the third insulating layer respectively at the first and second boundary areas. Each one of the first step compensation electrodes may partially overlap a respective one the trenches in a plan view, and each one of the second step compensation electrodes may partially overlap a respective one of the trenches in a plan view.

According to the embodiments of the present disclosure, because the first distance between the first reflective electrode and the cathode electrode in the first sub-pixel, the second distance between the second reflective electrode and the cathode electrode in the second sub-pixel, and the third distance between the third reflective electrode and the cathode electrode in the third sub-pixel may all be configured differently, light extraction efficiency of light of different colors, such as red, green, and blue light, in the sub-pixels of the organic light emitting diode display device can be increased by the micro cavity effect.

According to the embodiments of the present disclosure, by arranging the first step compensation electrodes formed coplanarly with the first reflective electrode of the first sub-pixel and arranging the second step compensation electrodes formed coplanarly with the second reflective electrode of the second sub-pixel and not overlapping the first step compensation electrodes under the trenches formed in the boundary areas between the first to third sub-pixels, it is possible to prevent steps from being formed on the insulating layer near the trenches.

Therefore, because the trenches may be formed in the desired normal shapes in the boundary areas between the first to third sub-pixels to disconnect the charge generation layer in the trench, the leakage current between the sub-pixels through the charge generation layer can be prevented or reduced. Further, the degradation of the image quality of the organic light emitting diode display device due to the leakage current can be prevented or reduced.

In addition, it is possible to prevent the steps from being formed on the insulating layer near the trenches, thereby preventing the occurrence of cracks, such as seams, of the encapsulation layer disposed on the trench and increasing the reliability of the display device.

In addition, according to one embodiment of the present disclosure, by applying the predetermined voltage to the first step compensation electrodes and the second step compensation electrodes disposed in the boundary areas between the first to third sub-pixels, the charges in the charge generation layer located on the bank in the boundary areas between the first to third sub-pixels can be prevented or reduced from flowing into the second stack of the light emitting layer, thereby preventing the generation of undesired light in the boundary areas between the first to third sub-pixels.

In addition, the low-power driving of the organic light emitting diode display device can be implemented with increased the light extraction efficiency. For example, the consumed power of the organic light emitting diode display device can be reduced by increasing the light extraction efficiency.

In addition, because the reliability of the organic light emitting diode display device increases, greenhouse gases generated by the manufacturing process of producing the new organic light emitting diode display device can be reduced.

The effects of the present disclosure are not limited to the above-described effects, and other effects that are not mentioned will be able to be clearly understood by those skilled in the art from the following description.

It will be apparent to those skilled in the art that various modifications and variations can be made in the display device of the present disclosure without departing from the technical idea or scope of the disclosure. Thus, it is intended that the present disclosure cover the modifications and variations of this disclosure provided they come within the scope of the appended claims and their equivalents.

What is claimed is:

1. An organic light emitting diode display device comprising an active area having a first sub-pixel, a second sub-pixel, and a third sub-pixel, and a non-active area adjacent to the active area, the organic light emitting diode display device comprising:
a substrate;
a first insulating layer on the substrate;
a first reflective electrode on the first insulating layer in the first sub-pixel;
a second insulating layer covering the first reflective electrode and on the first insulating layer;
a second reflective electrode on the second insulating layer in the second sub-pixel;
a third insulating layer covering the second reflective electrode and on the second insulating layer;
a third reflective electrode on the third insulating layer in the third sub-pixel;
trenches in the third insulating layer at respective boundary areas between the first, second, and third sub-pixels;
first step compensation electrodes on the first insulating layer at opposite sides of the second sub-pixel, each one of the first step compensation electrodes partially overlapping a respective one the trenches in a plan view; and
second step compensation electrodes on the second insulating layer at opposite sides of the first sub-pixel and at opposite sides of the third sub-pixel, each one of the second step compensation electrodes partially overlapping a respective one of the trenches in a plan view.

2. The organic light emitting diode display device of claim 1, wherein, in the plan view of the organic light emitting diode display device, the second step compensation electrodes do not overlap the first step compensation electrodes.

3. The organic light emitting diode display device of claim 1, wherein, in the plan view of the organic light emitting diode display device, the first step compensation electrodes do not overlap the second reflective electrode, and the second step compensation electrodes do not overlap the first reflective electrode and the third reflective electrode.

4. The organic light emitting diode display device of claim 1, wherein the first step compensation electrodes are spaced apart from the first reflective electrode in the plan view, and
wherein the second step compensation electrodes are spaced apart from the second reflective electrode in the plan view.

5. The organic light emitting diode display device of claim 1, wherein the first step compensation electrodes, the first reflective electrode, the second step compensation electrodes, and the second reflective electrode have a same thickness.

6. The organic light emitting diode display device of claim 1, wherein the first and second step compensation electrodes extend longer than the trenches in a length direction of the trenches.

7. The organic light emitting diode display device of claim 1, wherein the first and second step compensation electrodes extend from the active area to the non-active area, and a predetermined voltage is applied to the first and second step compensation electrodes.

8. The organic light emitting diode display device of claim 7, wherein a cathode line through which the predetermined voltage is applied to a cathode electrode is provided in the non-active area, and
wherein the first and second step compensation electrodes are electrically connected to the cathode line in the non-active area.

9. The organic light emitting diode display device of claim 7, wherein an external low potential voltage line is provided in the non-active area, and
wherein the first and second step compensation electrodes are electrically connected to the external low potential voltage line in the non-active area.

10. The organic light emitting diode display device of claim 7, wherein a first voltage is applied to the first step compensation electrodes, and
wherein a second voltage different from the first voltage is applied to the second step compensation electrodes.

11. The organic light emitting diode display device of claim 1, further comprising:
a first anode electrode on the third insulating layer in the first sub-pixel;
a second anode electrode on the third insulating layer in the second sub-pixel;
a third anode electrode on the third reflective electrode in the third sub-pixel; and
a bank on the third insulating layer,
wherein the bank covers edge areas of the first, second, and third anode electrodes, and
wherein, in the plan view, the first and second step compensation electrodes partially overlap a portion of the bank adjacent to the trenches.

12. The organic light emitting diode display device of claim 11, wherein, in a top view of the organic light emitting diode display device, the first step compensation electrodes do not overlap the second anode electrode, and the second step compensation electrodes do not overlap the first and third anode electrodes.

13. The organic light emitting diode display device of claim 1, wherein the first reflective electrode is absent in the second and third sub-pixels,
wherein the second reflective electrode is absent in the first and third sub-pixels, and
wherein the third reflective electrode is absent in the first and second sub-pixels.

14. A head mounted display device, comprising:
a left-eye eyepiece and a right-eye eyepiece; and
a left-eye display device and a right-eye display device configured to provide an image to the left-eye eyepiece and the right-eye eyepiece,
wherein each of the left-eye display device and the right-eye display device respectively includes the organic light emitting diode display device of claim 1.

15. An organic light emitting diode display device comprising an active area having a first sub-pixel, a second sub-pixel, and a third sub-pixel, and a non-active area adjacent to the active area, the organic light emitting diode display device comprising:
a substrate;
a first insulating layer on the substrate;
a first reflective electrode on the first insulating layer in the first sub-pixel;
a first step compensation electrodes on the first insulating layer at a first boundary area between the first and second sub-pixels and at a first boundary area between the second and third subpixels;
a second insulating layer on the first insulating layer, and covering the first reflective electrode and the first step compensation electrodes;
a second reflective electrode on the second insulating layer in the second sub-pixel;
second step compensation electrodes on the first insulating layer at the first boundary area and at the second boundary area;
a third insulating layer on the second insulating layer, and covering the second reflective electrode and the second step compensation electrodes; and
a third reflective electrode on the third insulating layer in the third sub-pixel,
wherein trenches are defined in the third insulating layer respectively at the first and second boundary areas;
wherein each one of the first step compensation electrodes partially overlap a respective one the trenches in a plan view, and
wherein each one of the second step compensation electrodes partially overlap a respective one of the trenches in a plan view.

16. The organic light emitting diode display device of claim 15, wherein, in the plan view of the organic light emitting diode display device, the second step compensation electrodes do not overlap the first step compensation electrodes.

17. The organic light emitting diode display device of claim 15, wherein, in the plan view of the organic light emitting diode display device, the first step compensation electrodes do not overlap the second reflective electrode, and the second step compensation electrodes do not overlap the first reflective electrode and the third reflective electrode.

18. The organic light emitting diode display device of claim 15, wherein the first step compensation electrodes are spaced apart from the first reflective electrode in the plan view, and
wherein the second step compensation electrodes are spaced apart from the second reflective electrode in the plan view.

19. The organic light emitting diode display device of claim 1, wherein the first step compensation electrodes and the first reflective electrode have a first thickness, and
wherein the second step compensation electrodes and the second reflective electrode have a second thickness.

20. The organic light emitting diode display device of claim 15, wherein the first reflective electrode is absent in the second and third sub-pixels,
wherein the second reflective electrode is absent in the first and third sub-pixels, and
wherein the third reflective electrode is absent in the first and second sub-pixels.

21. The organic light emitting diode display device of claim 15, wherein the first step compensation electrodes are coplanar with the first reflective electrode, and
wherein the second step compensation electrodes are coplanar with the second reflective electrode.
